(19) United States
(12) Patent Application Publication
(10) Pub. No.: US 2025/0029856 A1
(43) Pub. Date: Jan. 23, 2025

(54) METHOD AND DEVICE FOR FRONT GAS DELIVERY INTO A CONTAINER

(71) Applicant: ENTEGRIS, INC., Billerica, MA (US)

(72) Inventors: Mark V. Smith, Colorado Springs, CO (US); Shawn D. Eggum, Lonsdale, MN (US); Aleksandr A. Yakuba, Colorado Springs, CO (US)

(21) Appl. No.: 18/778,876

(22) Filed: Jul. 19, 2024

Related U.S. Application Data
(63) Continuation-in-part of application No. 18/648,149, filed on Apr. 26, 2024.
(60) Provisional application No. 63/528,289, filed on Jul. 21, 2023.

(51) Int. Cl. H01L 21/673

(52) U.S. Cl. CPC H01L 21/67389

(57) ABSTRACT

A substrate container that includes a shell, a connector, and a gas distributing device. The connector is connected to an opening provided on a side wall of the shell, in which the connector includes a base portion having an inlet and an outlet and a connector body having a first end and a second end. The first end of the connector body is rotatably connected with the outlet of the base portion, and second end of the connector body is connected to the opening of the shell. The gas distributing device connector includes a first end and a second end, in which the first end of the gas distributing device connector is connected with the second end of the connector body and a second end of the gas distributing device connector is configured to connect with a gas distributing device.

### FIELD

This disclosure is directed to methods and systems for controlling or distributing gas into a container. More specifically, this disclosure relates to a purge flow distribution system for controlling or distributing flow of purge gas into a front portion of a substrate container and modules thereof.

### BACKGROUND

Substrates, for example, in the form of wafers, can be processed to form semiconductor devices. The wafer substrates, or simply substrates, undergo a series of process steps. Exemplary process steps can include, but are not limited to, material layer deposition, doping, etching, or chemically or physically reacting material(s) of the substrate. A substrate container is used to store and transport the in-process wafers between process steps within the fabrication facility. During some process steps, the substrates are processed by processing equipment within a clean environment (e.g., a clean room). During processing, gasses must be introduced and removed from the substrate container such as a front opening unified pods (FOUP), for example during purge processes, thus requiring that the FOUP have one or more locations at which purge gas may enter or leave the FOUP. Substrates can be transferred from the substrate container to the processing tool through an equipment front end module (EFEM). The EFEM generally includes a load port for receiving the substrate container, a transfer unit, a frame or “mini-environment”, and a fan filter unit used to generate gas flow within the EFEM.

In use, the substrate container can be docked on a load port. Next, the door is disengaged from the substrate container which permits the transfer unit housed within the EFEM to access the substrates contained within the substrate container for processing. A flow of gas introduced by the fan filter unit flows through the EFEM in a direction from a top of the EFEM to a bottom of the EFEM. When the front opening of the substrate container interfaces with the load port opening of the EFEM some of the gas flowing through the EFEM and across the load port opening may be inadvertently directed into the interior of the container, potentially interfering with the purging capabilities of the substrate container by temporarily causing an increase in the relative humidity or oxygen levels within the microenvironment of substrate container, which can be undesirable.

Purge gases can be used to remove or prevent entry of contaminants to protect the substrates and improve yield for the processing of those substrates, e.g., wafers. The purge gases are typically provided by diffusers, for example, diffuser towers, provided for each port configured to receive purge gas, providing a standard flow rate based on the supply of purge gas to the port, which are installed in the substrate container by placing the diffuser into the container and attaching the diffuser to a fitting provided inside the wafer container. Purge assemblies can direct the received flow of purge gas to a diffuser, to be provided at a particular location within the wafer container.

Containers used in substrate processing can be purged, using a suitable purge gas to drive out moist air or other potential contaminants to protect the wafers and improve yield for the processing of those substrates. The purge can be provided to the interior of the container using a purge assembly. Purge assemblies for substrate containers such as front-opening unified pods (FOUPs) typically include multiple discrete components including a grommet, a valve such as a check valve, and various sealing members. Diffusers can be installed to the purge assembly once it is installed in the substrate container by placing the diffuser into the container and attaching the diffuser to a fitting provided inside the substrate container. Purge assemblies can direct the received flow of purge gas to a diffuser, to be provided at a particular location within the substrate container. Filters are typically retained by fastening them into place in a filter element that is then included in the purge assembly. The filters are typically circular in shape.

### SUMMARY

This disclosure is directed to methods and systems for controlling or distributing purge gas for substrate containers, e.g., wafer or reticle carrying containers, such as FOUPs or pods (e.g., reticle pods) that are used, for example, in semiconductor manufacturing. More specifically, this disclosure relates to a purge flow distribution system or purge gas assembly for controlling or distributing flow of purge gas at least into a front portion of a substrate container and modules thereof.

The purge flow distribution system or purge gas assembly is configured to supply a flow of purge gas into an interior space of the substrate container by dividing the stream of purge gas, and preferably into a first flow path to supply a rear gas distributing device and a second flow path to supply a front gas distributing device. In some embodiments, the purge gas assembly can be configured to prevent ingress of gas into the front opening of the substrate container while open or as an outlet to facilitate the exhaustion of purge gas from the substrate container when the substrate container is closed. The purge gas assembly can include one or more of purge module(s), the gas distributing device(s), gas distributor(s), control valve(s), piping, etc.

The purge module(s) can be configured to filter a received flow and direct a first portion of the filtered received flow to a rear gas distributing device, e.g., rear diffuser, and a second portion of the filtered received flow to a front gas distributing device, e.g., an amplifier, front diffuser, or manifold, etc., of a substrate container, allowing purge operations in the substrate container to be improved through additional points of introduction of the purge gas.

The purge module can be configured such that the rear diffuser can be attached to the purge module prior to attachment to the substrate container, and the substrate container and purge module can be configured such that the assembled diffuser can be inserted into an interior space of the shell of the substrate container from an exterior of said shell of the substrate container to install the diffuser into the substrate container. This can allow the insertion of the purge module and diffuser by minimally requiring any operations be performed inside the shell of the substrate container. Similarly, the amplifier, front diffuser, or manifold, etc. can be connected to the purge gas assembly after the purge gas assembly has been connected to the substrate container by a partial insertion of the front diffuser inside the shell of the substrate container with minimal operations occurring inside the shell, e.g., especially in portions of the interior space of the substrate container in which the substrates can be installed. This can reduce the likelihood of installation errors and/or reduce particle generation or addition of contaminants within the shell of the substrate container. This can in turn reduce the loss of wafers and improve yields from processes using substrate containers including such purge modules and diffusers.

In an embodiment, to allow connection of the front gas distributing device, e.g., an amplifier, diffuser, or manifold, etc., to the purge gas assembly, a connector is provided. The connector includes a base portion having an inlet and an outlet, in which the inlet is configured to connect with a tubing connected to the purge gas assembly and a connector body having a first end and a second end, in which the first end is configured to rotatably connect with the outlet of the base portion, and the second end is configured to connect to an opening provided on a substrate container.

In another embodiment, a substrate container having a purge gas assembly is provided. The substrate container includes a shell, a connector connected to an opening provided on a side wall of the shell, in which the connector includes a base portion having an inlet and an outlet and a connector body having a first end and a second end, in which the first end of the connector body is rotatably connected with the outlet of the base portion, and second end of the connector body is connected to the opening of the shell. A gas distributing device connector can be further included that includes a first end and a second end, in which the first end of the gas distributing device connector is connected with the second end of the connector body and a second end of the gas distributing device connector is configured to connect with a gas distributing device.

In yet another embodiment, a method for assembling a substrate container having a gas distributing device is provided. The method includes connecting an outlet of a connector through a front purge port provided on a shell of the substrate container; connecting a gas distributing device to a second end of a gas distributing device connector; and connecting a first end of the gas distributing device connector with the outlet of the connector to connect the gas distributing device to the substrate container.

As such, the substrate container having the purge gas assembly or the purge gas assembly connector, as discussed herein, have at least the following benefits:

A structure that is configured to deliver purge gas to front gas distributing devices, such as, amplifiers, manifolds, or diffusers, etc., from existing rear purge gas inlet locations, in which the purge gas is delivered through or along the substrate container shell into the front gas distributing devices.

A structure that is configured to control or distribute purge gas from the rear purge gas inlet locations to the front of the substrate container by dividing or diverting portions of the purge gas such that the amount of purge gas can be adjusted for optimal performance.

A method to transport or control the flow of the purge gas from the inlet location(s) to the gas distributing devices inside the substrate container, and, especially, from a rear purge module to the front gas distributing devices and an assembly structure for allowing the same.

A method and structure that allows installation and insertion of the gas distributing devices into the substrate container without requiring (or minimally requiring) any operations to be performed inside the substrate container, e.g., especially in portions of the interior space of the substrate container in which the substrates can be installed. As such, such installation can reduce the likelihood of installation errors or reduce particle generation or addition of contaminants within the container body or shell of the substrate container. This can in turn reduce the loss of substrates, such as wafers, and improve yields from processes using substrate containers that include the purge gas assembly(s) or gas distributing device(s).

### BRIEF DESCRIPTION OF DRAWINGS

FIG. 1 shows an exploded view of a substrate container having a purge gas assembly, according to an embodiment.

FIG. 2 illustrates an exploded view of a connector for a purge gas assembly, according to an embodiment.

FIGS. 3A and 3B show a sectional and assembly view of a connector for a purge gas assembly, according to an embodiment.

FIGS. 4A, 4B, 4C show a gas distributing device attached to a connector for a purge gas assembly attached to a substrate container, according to an embodiment.

FIG. 5 shows a flowchart for assembling a substrate container having a gas distributing device, according to an embodiment.

### DETAILED DESCRIPTION

While the terms “front” and “rear” and “right” and “left” are used herein for describing various elements, the elements are not limited by these terms. Rather, the terms are only used to distinguish one element from another. Instead, the terms are interpreted broadly to include any positional relationship between the elements including, the front, the back, the sides, the top, the bottom, or any combination thereof without departing from the scope of the present disclosure.

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

As used herein, the term “substrate” can refer to wafers, reticles, panels, or trays that can be processed to form semiconductor devices.

As used herein, the term “substrate container” can refer to wafer or reticle carrying containers, such as, front opening unified pods (FOUPs) or pods (e.g., reticle pods) that are used, for example, in semiconductor manufacturing. The “substrate container” can include five sides or walls that define an interior space and an opening to receive a door. The “substrate container” can further include substrate shelves, a top automation feature, and a bottom plate with automation interfaces.

As used herein, the term “gas distributing device” can refer to amplifiers diffusers, manifolds, membranes, portions having slits or nozzles or is made of porous material, elbows, or flow diverters, or similar structures that is able to direct the purge gas into the interior of the substrate container.

As used herein, the term “gas distributor” can refer to a plenum, manifold, or other gas distributing structure that has one or more outlets for distributing a gas.

As used herein, the term “sealing ring” can refer to a lip seal, an O-ring, sealing gasket, or other compressible mechanical gasket material, for example, polymeric or elastomeric material, or resilient material.

As used herein, the term “resilient material” can be a fluoroelastomer, for example Viton™, FKM, a thermoplastic elastomer, a thermoplastic olefin, a thermoplastic polyurethane, or the like.

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

This disclosure is directed to methods and systems for controlling or distributing purge gas for substrate containers, e.g., wafer or reticle carrying containers, such as, front opening unified pods (FOUPs) or pods (e.g., reticle pods) that are used, for example, in semiconductor manufacturing. The substrate container is a container for carrying substrates during different processing steps, in which the substrates can be in the form of wafers, reticles, panels, or trays that can be processed to form semiconductor devices. The substrate container is accessed through a front opening of the substrate container. More specifically, this disclosure relates to a purge gas assembly for controlling or distributing flow of purge gas into at least a front portion of a substrate container, in which the purge gas assembly is configured to supply a flow of purge gas into an interior space of the substrate container by dividing the stream of purge gas, and preferably into a first flow path to supply a rear distributing device and a second flow path to supply a front gas distributing device. In some embodiments, the purge gas assembly can be configured to prevent ingress of gas into the front opening of the substrate container while open or as an outlet to facilitate the exhaustion of purge gas from the substrate container when the substrate container is closed. The purge gas assembly can include one or more of purge module(s), the gas distributing device(s), gas distributor(s), control valve(s), piping, etc.

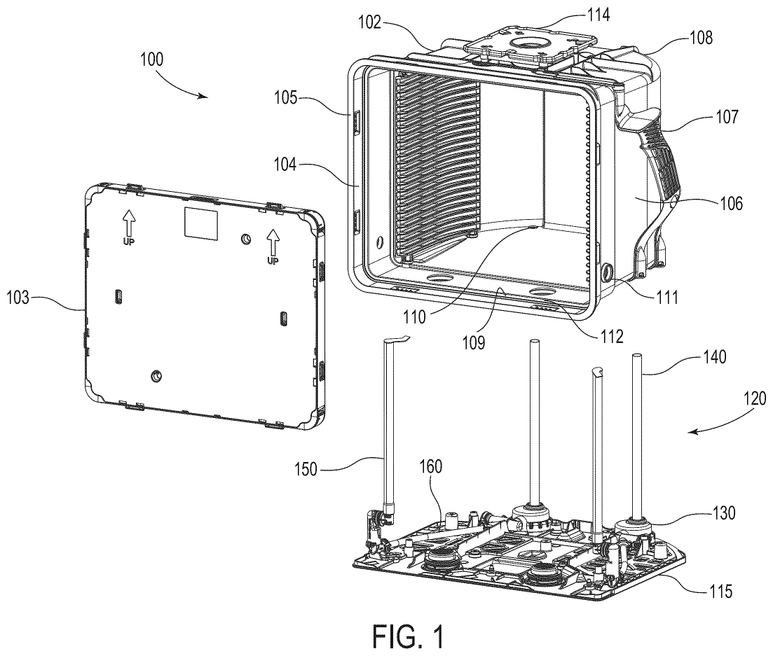

FIG. 1 shows an exploded view of a substrate container 100, carrier (or conveyor) plate 115, and purge gas assembly 120 for supplying purge gas to the substrate container 100, according to an embodiment. In an embodiment, the purge gas assembly 120 can be configured to filter a received flow of purge gas and direct a first portion of the purge gas to a rear gas distributing device, and a second portion of the purge gas to at least a front gas distributing device to allow purging operations in the substrate container to be improved through additional points of introduction of the purge gas, as discussed further below. While the description below describes components as being in the rear or front, such disclosure is not intended to be limiting, but rather, provided to distinguish one element from another. It is appreciated that the components can be in any positional relationship in different positions of the substrate container to allow for purging through additional points of introduction of the purge gas.

Substrate container 100 includes shell 102, e.g., container body, and front door 103. Substrate container 100 is a container configured to accommodate one or more substrates for transport, storage, or processing of the substrates. The substrates contained in substrate container 100 can be, for example, semiconductor substrates such as wafers. The substrate container 100 can be any suitable container for the substrate, such as a front opening uniform pod (FOUP). In an embodiment, the substrate container 100 can be a container for a reticle, such as a reticle pod. In such an embodiment, the shell 102 can be included as at least part of an outer pod configured to contain an inner pod.

Shell 102 defines an interior space 104 configured to contain one or more substrates, such as wafers, for processing. A front opening, e.g., via removal of the front door 103, can allow the substrates to be inserted into or removed from shell 102. The shell 102 includes a first side wall 105, a second side wall 106, a rear wall 107, a top wall 108, and a bottom wall 109. The substrate container 100 can include one or more rear inlet purge port(s) 110 and one or more front inlet purge port(s) 111 corresponding to inlet(s) of the substrate container 100 and one or more outlet purge port(s) 112 corresponding to outlet(s) of the substrate container 100. The inlet purge port or the outlet purge ports can be provided at various locations on the substrate container 100 including, but not limited to, on the bottom wall 109 or the first side wall 105 and second side wall 106, The one or more rear inlet purge port(s) 110 or the one or more front inlet purge port(s) 111 can be connected to the purge gas assembly 120. The one or more front inlet purge port(s) 111 can be a hole or opening in the first side wall 105 or the second side wall 106 for connecting to the purge gas assembly 120, as further discussed below. The one or more outlet purge port(s) 112 can be provided for discharging gas in the interior space 104 out of the substrate container 100 and can be disposed in the bottom wall 109. It is appreciated that the inlet purge port(s) 110, 111 or outlet purge port(s) 112 can also be provided in different positions along the shell 102 to allow for purging through additional points of introduction or removal of the purge gas, e.g., in the rear wall 107.

The substrate container 100 can also include a top automation feature, such as, an equipment hookup 114 on the top wall of the shell 102. In an embodiment, the equipment hookup 114 can allow a standard automated attachment (not shown) for moving the substrate container 100, such as, but not limited to an automated arm, to be connected to the substrate container 100. For example, the automated arm may be used to move the substrate container 100 between different processing equipment. In an embodiment, the substrate container 100 may include one or more handles (not shown) to allow a user (e.g., a technician, etc.) to manually move the substrate container 100.

The bottom plate 115 can provide a base that the shell 102 can be attached to or be a base that the purge gas assembly 120 can be attached to. The bottom plate 115 can be a carrier plate or conveyor plate with an automation interface that is configured to attach to a conveyor system for the processing of the substrate or assembly of the substrate container 100.

The purge gas assembly 120 can include one or more of purge module(s), one or more gas distributors, one or more gas distributing device(s), control valve(s), piping, etc. The purge gas assembly 120 is configured to distribute purge gas to one or more gas distributing devices, and specifically, to at least one front gas distributing device. The purge flows can be of any suitable gas that does not contaminate the environment within shell 102. Non-limiting examples of the purge flow gas can be nitrogen, clean dry air (CDA), or the like. The purge gas assembly 120 includes a combination of a gas distributor and purge module 130. The purge module can have an inlet for receiving a flow of purge gas, a check valve for regulating a flow direction of the purge gas, and an outlet for supplying the purge gas. The purge module can be configured such that the rear gas distributing device 140, e.g., a diffuser or manifold, can be attached to the purge module or to the combination of the gas distributor and purge module 130. In some embodiments, the purge gas assembly 120 can include at least two of the combinations of gas distributors and purge modules 130 for providing purge gas to right and left sides of the substrate container 100, in which each of the combination of gas distributors and purge modules 130 is configured to supply purge gas to one or more of a rear gas distributing device for a rear portion of the substrate container 100, a front gas distributing device 150 for a front portion of the substrate container 100, or other purge port(s) on the substrate container 100. In some embodiments, the purge gas assembly 120 can be configured such that the rear gas distributing device(s) 140 can be attached directly to the purge gas assembly 120, or a portion thereof, for providing the purge gas inside the substrate container 100. In some embodiments, the front gas distributing device(s) 150 can be attached to the purge gas assembly 120 or the shell 102.

In some embodiments, the purge gas assembly 120 can also include a control valve connected to the combination of the gas distributor and purge module 130, in which the control valve is configured to control the distribution of the flow of purge gas, and tubing 160 for connecting the combination of the gas distributor and purge module 130 to at least one front gas distributing device 150 for distributing purge gas to a front of the substrate container 100. The tubing 160 can be a flexible polymer tube that is formed from a fluoropolymer, such as, perfluoroalkoxy alkanes (PFA), or polyethylene, such as, high density polyethylene (HDPE), or similar compatible material for substrate processing. In an embodiment, to allow the purge gas assembly 120 to be pre-assembled outside the substrate container on the bottom plate 115, the tubing 160 can be configured to be assembled with a reliable connection system with the control valve or a front gas distributing device connector. In an embodiment, the reliable connection system can include a snap-fit connector and scaling ring, such as an O-ring, sealing gasket, or other compressible mechanical gasket material, for example, polymeric or elastomeric material. As such, one end of the tubing 160 can be inserted into the control valve and the sealing ring placed along an outer surface of the tubing 160, such that when the snap-fit connector is snapped together with the control valve, the sealing ring is compressed to fluidly seal the tubing 160 with the control valve. Similarly, the other end of the tubing 160 can be inserted into the front gas distributing device connector and the sealing ring placed along an outer surface of the tubing 160, such that when the snap-fit connector is snapped to the front gas distributing device connector, the scaling ring is compressed to fluidly seal the tubing 160 with the front gas distributing device connector. The snap-fit connector can include flexible components that can deform when a force is applied, e.g., using a twisting or pushing force, such that an interlocking occurs with the corresponding component when in the final position, e.g., restoration of the components. As such, a reliable connection system can be provided for pre-assembling the purge gas assembly 120 on a bottom plate 115, such that the purge gas assembly 120 can be pre-assembled and when the bottom plate 115 and purge gas assembly 120 are attached to a substrate container, the purge module, and optionally including the diffuser(s), can be inserted into the purge gas assembly 120 or substrate container from outside the substrate container with no or minimal intrusion into the interior space of the substrate container for assembling of the same.

It is appreciated that while the purge gas assembly 120 is discussed herein as including a control valve, such disclosure is not limiting, since other devices can be used to control or regulate the flow of purge gas through the purge gas assembly 120 to the front gas distributing device 150. For example, in some embodiments, an orifice, spring loaded diverter, or tubing or piping/pipes that have smaller or larger cross-sectional areas can be used to regulate the flow of purge gas.

As discussed above, in some embodiments, some of the components, such as, the purge module, can be assembled or attached separately from the purge gas assembly 120, e.g., modular components. As such, at least portions of the purge gas assembly 120 can be pre-assembled on the bottom plate 115 and attached to the substrate container 100. In some embodiments, the purge module or the front gas distributing device, e.g., amplifier, diffuser, or manifold, can be assembled or attached to the purge gas assembly 120 after the purge gas assembly 120 has been attached to the substrate container 100 such that the purge module or front gas distributing device can be installed without requiring (or minimally requiring) any operations be performed inside the shell 102 of the substrate container 100, e.g., especially in portions of the interior space of the substrate container in which the substrates can be installed.

By being able to install some components of the purge gas assembly 120, and specifically, the purge module (and the rear gas distributing device) or front gas distributing device, primarily from outside or with minimal intrusion into the interior spaced defined by substrate container 100 such installation can reduce the likelihood of installation errors or reduce particle generation or addition of contaminants within the container body or shell of the substrate container. This can in turn reduce the loss of substrates, such as wafers, and improve yields from processes using substrate containers that include the purge gas assembly(s) or gas distributing device(s). In some embodiments, the purge gas assembly 120 can be configured such that the purge gas assembly 120 includes any of its components, including any gas distributing devices (not including the front gas distributing device), such as, a diffuser or manifold, attached together prior to attachment to the substrate container 100. In other embodiments, the different components of the purge gas assembly 120 can be modular in that the different components can be removed or modified, as necessary.

Referring back to FIG. 1, the purge gas assembly 120 can be attached to a top surface of the bottom plate 115 or integrally formed therewith. In an embodiment, a portion of the purge gas assembly 120 can be located within the shell 102. In an embodiment, the purge gas assembly 120 can be located adjacent to the shell 102. In an embodiment, the purge gas assembly 120 can be at least partially disposed between the shell 102 and the bottom plate 115. While the purge gas assembly 120 is discussed herein as being attached to the bottom plate 115, such disclosure is not intended to be limiting. In an embodiment, the purge gas assembly 120 can be attached to the bottom wall of the shell 102 or provided between the substrate container 100 and the bottom plate 115.

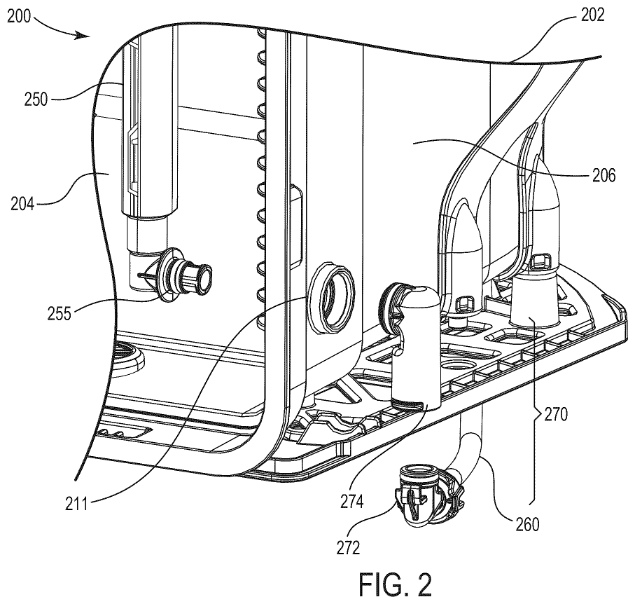

FIG. 2 shows an exploded view of a connection between a purge gas assembly, e.g., 120 of FIG. 1, with a substrate container 200 and front gas distributing device 250 using a connector 270, according to an example embodiment. That is, as illustrated in FIG. 2, in order to facilitate minimal operations of assembling the purge gas assembly from inside the shell of the substrate container, the purge gas assembly can include the connector 270 for connecting the purge gas assembly to the shell of the substrate container 200. The substrate container 200 has at least a shell 202 having an interior space 204 and a side wall 206, in which the side wall 206 includes at least a front purge port 211 for receiving the gas distributing device 250, such as, a diffuser or manifold, and the purge gas assembly having the connector 270.

The purge gas assembly, e.g., 120 of FIG. 1, includes tubing 260 connected to the combination of gas distributor and purge module, e.g., 130 of FIG. 1, or components therebetween at one end thereof, and the connector 270 connected to the other end of the tubing 260, as discussed above. The connector 270 is connected to or through the front purge port 211 to the front gas distributing device 250, as further discussed below. As such, the purge gas assembly is configured to deliver purge gas from the rear purge inlet at the combination of gas distributor and purge module, e.g., 130 of FIG. 1, to the front gas distributing device 250 through the substrate container 200, e.g., through the shell of the substrate container to the front gas distributing device(s). That is, since the purge gas assembly includes the control valve, tubing, and the connector to distribute or control the purge gas through the shell to the front gas distributing device(s), e.g., amplifier, diffuser, or manifold, the purge gas can be diverted from the rear inlet ports to the front purge ports and front gas distributing devices, e.g., inside a FOUP. Moreover, since the components of the purge gas assembly, e.g., the control valve, tubing, and the connector, can be configured to have a twist-lock or snap-fit connection and scaling, e.g., using a scaling ring, the components can be easily installed and connected together prior to combining with the substrate container. Such twist-lock or snap-fit connection also can allow the front gas distributing device, e.g., amplifier, diffuser, or manifold, to be removed and replaced from the substrate container by simply rotating to lock or un-lock it from the connector or shell of the substrate container, as further discussed below.

The connector 270 includes a base portion 272 that has an inlet and an outlet, in which the inlet can be connected to the tubing 260 and a connector body 274 having a first end and a second end, in which the first end is configured to rotatably connect with the outlet of the base portion, and the second end is configured to connect to the front purge port 211 of the substrate container 200. In some embodiments, the connector body 274 and the base portion 272 can include corresponding locking portions that are configured to provide a locking connection between the connector body and the base portion by a rotation of the connector body received on the outlet of the base portion. In other embodiments, the connector body 274 can have a snap-fit connection with the base portion 272. The snap-fit connection can include flexible components that can deform when a force is applied, e.g., using a twisting or pushing force, such that an interlocking occurs with the corresponding components when in the final position, e.g., restoration of the components. In some embodiments, the connector 270 can be integrally molded as a single piece having the base portion 272 and the connector body 274 formed together.

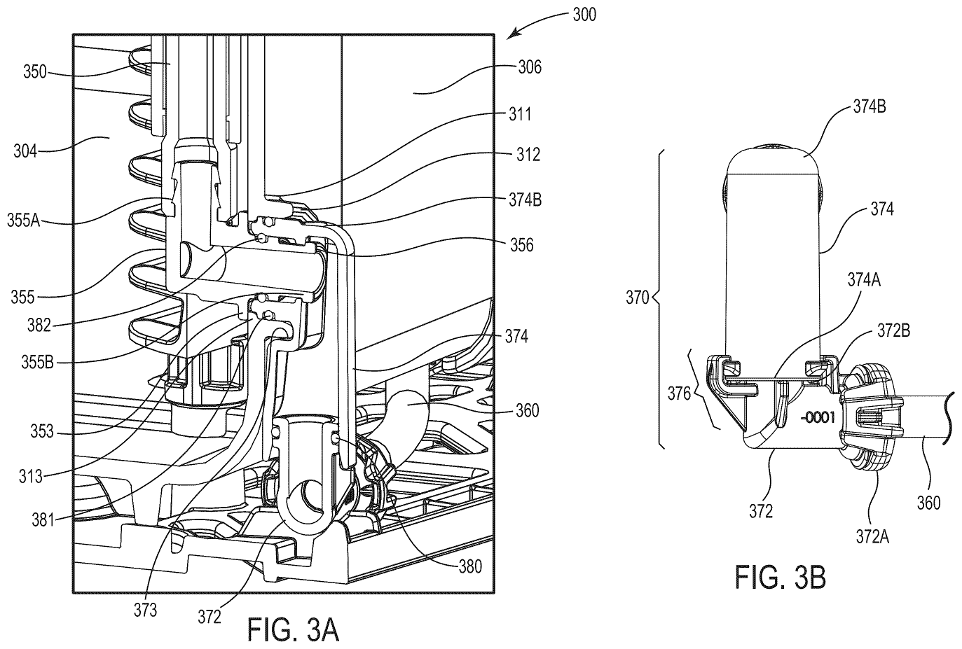

The second end of the connector body 274 is not only configured to connect to the front purge port 211 of the substrate container 200, but also configured to connect to a gas distributing device connector 255 connected to the gas distributing device 250, as further discussed below in reference to FIGS. 3A and 3B. The connection between the second end of the connector body 274 and the gas distributing device connector 255 can be a locking connection. In some embodiments, the locking connection can be provided by a rotation of the gas distributing device 250 having the gas distributing device connector 255 received in the connector 270. In some embodiments, the locking connection can be provided by a snap-fit connection. The above disclosure is not intending to be limiting, in which other locking connections can be used, for example, cam-type locks, screw couplings, screw links, or the like.

FIGS. 3A and 3B show a cross-sectional view of and assembled rear view of a connection between a purge gas assembly, e.g., 120 of FIG. 1, with a substrate container 300 and front gas distributing device 350 using a connector 370 and gas distributing device connector 355, according to an example embodiment. The substrate container 300 has at least an interior space 304 and a side wall 306, in which the side wall 306 includes at least a front purge port 311 for receiving the gas distributing device 350, such as, a diffuser or manifold, and the gas distributing device connector 355 and the purge gas assembly having the connector 370. The front purge port 311 can be a hole or opening in the side wall 306 with walls 312 forming the front purge port 311 extending therefrom. In some embodiments, the front purge port 311 can include along an inner surface of the side wall 306, protrusions 313 that extend at least partially into the opening or hole in the side wall 306 forming the front purge port 311.

The connector 370, which can have the same or similar features as the connector 270 of FIG. 2, includes a base portion 372 that has an inlet 372A and an outlet 372B, in which the inlet 372A can be connected to the tubing 360, as discussed above, and a connector body 374 having a first end 374A and a second end 374B, in which the first end 374A is configured to rotatably connect with the outlet 372B of the base portion 372, and the second end 374B is configured to connect to the front purge port 311 of the substrate container 300. The connector 370 can have the inlet 372A disposed at an angle with respect to the second end 374B. In an embodiment, the angle can be between 60 and 120 degrees, and in some embodiments, at or about 90 degrees, e.g., ±5%.

In an embodiment, the rotatable connection between the connector body 374 and the base portion 372 can include providing the first end 374A of the connector body 374 over an outer surface of the outlet 372B of the base portion 372. In some embodiments, a sealing ring 380 can be provided on the outer surface of the outlet 372B of the base portion 372 to provide a fluidly sealed connection between the connector body 374 and the base portion 372. In some embodiments, once the first end 374A of the connector body 374 is provided over the outlet 372B of the base portion 372, locking portions 376 can be used to provide a locking connection between the connector body 374 and the base portion 372. In an embodiment, the locking portions 376 can include corresponding lips and ledges such that after the connector body 374 is provided over the base portion 372, the connector body 374 can be rotated to provide the locking engagement. The lips and ledges can include corresponding incline portions for securing the locking connection in a further fluidly sealed manner. In other embodiments, the connector body 374 can have a snap-fit connection with the base portion 372. The snap-fit connection can include flexible components that can deform when a force is applied, e.g., using a twisting or pushing force, such that an interlocking occurs with the corresponding components when in the final position, e.g., restoration of the components.

The second end 374B of the connector body 374 is configured to connect to at least one of the front purge port 311 of the substrate container 300 or a gas distributing device connector 355 connected to the gas distributing device 350, e.g., via inner or outer surfaces. The connection between the second end 374B of the connector body 374 and the front purge port 311 can be as follows. The second end 374B of the connector body 374 can include an abutment portion and cavity 373 for connecting to the front purge port 311. In an embodiment, the second end 374B of the connector body 374 can be inserted into the front purge port 311 such that the abutment portion at the second end 374B abuts the protrusion 313 formed along the inner surface of the side walls 306. The cavity 373 of the second end 374B of the connector body 374 can be configured to accommodate the walls 312 forming the front purge port 311 such that a main body of the connector body 374 can be adjacent the shell of the substrate container 300. A sealing ring 381 can be provided on the outer surface of the second end 374B such that when the second end 374B is inserted into the walls 312 of the front purge port 311 a fluidly sealed connection is provided.

In an embodiment, the second end 374B of the connector body 374 and the front purge port 311 can include engagement features for securing and connecting the second end 374B to the shell of the substrate container 300. In an embodiment, the engagement features can include, but not limited to, threaded engagements, snap-fit connections, lips and ledges, press-fit connections, or the like. While the connector 370 has been discussed with respect to having two components, it is understood that such disclosure is not intended to be limiting. In some embodiments, the connector 370 can be a single molded piece that is integrally molded having an inlet connected to the tubing and an outlet connected to the front purge port 311 or the front gas distributing device connector 355.

In an embodiment, the gas distributing device connector 355 can connect to the second end 374B of the connector body 374. The gas distributing device connector 355 includes a first end 355A and a second end 355B. The first end 355A and the second end 355B can be disposed at an angle with respect to each other. In some embodiments, the angle can be at or about 90-degree angle. The first end 355A can include threaded portions for connecting to the gas distributing device 350, e.g., diffuser or manifold. The threaded portions can be configured to provide a screw connection, ribbed connection, or press-fit connection between the gas distributing device connector 355 and the gas distributing device 350.

The second end 355B of the gas distributing device connector 355 includes an abutment portion 353 and a locking portion 356. The abutment portion 353 is configured to engage an interior portion or surface of the shell of the substrate container, e.g., along the inner surface of the side wall 306. In some embodiments, the abutment portion 353 can abut against the protrusions 313. As such, when the gas distributing device connector 355 is connected with the connector 370, the abutment portion 353 can be configured to prevent or limit the extension of the second end 355B of the gas distributing device connector 355 out of the shell of the substrate container 300 or provide an opposing surface for providing a secured connection with the connector 370, e.g., counter forces to securing the gas distributing device to the substrate container 300 or purge gas assembly.

The locking portion 356 of the second end 355B of the gas distributing device connector 355 can be a protrusion or tab that is configured to engage with a corresponding locking portion provided along an inner surface of the second end 374B of the connector 370. As such, after the second end 355B of the gas distributing device connector 355 is inserted into the second end 374B of the connector 370, the locking connection can be provided by a rotation of the gas distributing device connector 355 inside the connector 370 such that the locking portion 356 of the second end 355B engages with the corresponding locking portion inside the second end 374B of the connector 370. In some embodiments, the locking portion 356 or the corresponding locking portion can include inclined portions such that the rotation of the gas distributing device connector 355 provides a further secured connection between the gas distributing device connector 355 and the connector 370. In some embodiments, the locking connection can be provided by a snap-fit connection. The above disclosure is not intending to be limiting, in which other locking connections can be used, for example, cam-type locks, screw couplings, screw links, or the like. In some embodiments, a sealing ring 382 can be provided along an outer surface of the second end 355B of the gas distributing device connector 355 to provide a fluidly sealed connection. Moreover, while the gas distributing device connector 355 has been discussed herein as being connected to the connector 370, it is understood that the gas distributing device connector 355 can be directly connected to the shell of the substrate container 300 using the same or similar structures as discussed above.

As such, by having the gas distributing device connector 355 and connector 370 as discussed herein, such combination allows the front gas distributing device 350 to be removed or replaced by simply rotating the amplifier, diffuser, or manifold to lock or unlock the front gas distributing device from the substrate container 300. As such, a simple and effective purge gas assembly can be provided to transport purge gas from an inlet and a rear purge module to a front gas distributing device via a flexible polymer tube through the shell of the substrate container without having to modify the substrate container or drill holes into the bottom plate, in which the components can be simply twist-locked or snap-fit connected together to provide reliable connections. Such purge gas flow distribution can be routed within existing FOUP geometries with minimal modifications, e.g., since the pre-assembly of the purge gas assembly can be done externally of the substrate container.

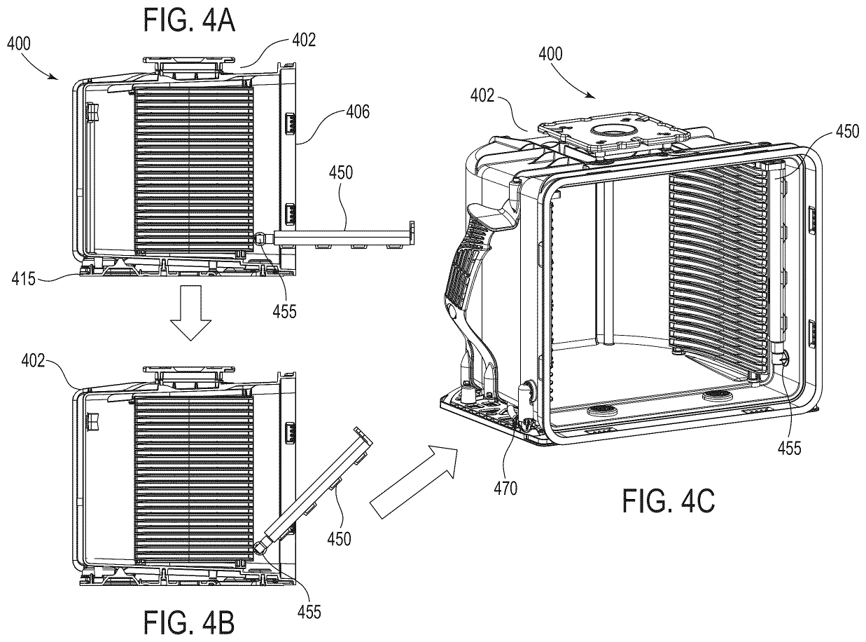

FIGS. 4A, 4B, 4C illustrate a connection or assembly of a gas distributing device 450 to the substrate container 400 or purge gas assembly, e.g., 120 of FIG. 1, on bottom plate 415. As illustrated in FIG. 4C, the purge gas assembly includes a connector 470 that is connected to tubing of the purge gas assembly for controlling or distributing a filtered flow of purge gas and direct a first portion of the purge gas to a rear gas distributing device, and a second portion of the purge gas to at least the front gas distributing device to allow purging operations in the substrate container to be improved through additional points of introduction of the purge gas. The connector 470 can be connected to the purge gas assembly and the side wall 406 of the shell 402 of the substrate container 400 in any of the ways as discussed above. The gas distributing device 450 includes the gas distributing device connector 455 connected thereto, e.g., threaded portions to provide a press-fit, snap-fit, screw fit, or the like type connection.

As seen in FIG. 4A, the gas distributing device connector 455 can connect to the connector 470 (not shown in the figure) by including a first end and a second end. The first end and the second end can be disposed at an angle with respect to each other. In some embodiments, the angle can be at or about 90-degree angle. The first end of the gas distributing device connector 455 is connected to the gas distributing device 450 and the second end of the gas distributing device connector 455 is inserted into the connector 470. In an embodiment, the second end of the gas distributing device connector 455 includes an abutment portion and a locking portion. The abutment portion is configured to engage an interior portion or surface of the shell 402 of the substrate container, e.g., along the inner surface of the side wall 406. As such, when the gas distributing device connector 455 is connected with the connector 470, the abutment portion can be configured to prevent or limit the extension of the second end of the gas distributing device connector 455 out of the shell of the substrate container 400 or provide an opposing surface for providing a secured connection with the connector 470, e.g., counter forces to securing the gas distributing device to the substrate container 400 or purge gas assembly.

The locking portion of the second end of the gas distributing device connector 455 can be a protrusion or tab that is configured to engage with a corresponding locking portion provided along an inner surface of the second end of the connector 470. As such, when initially connecting the second end of the gas distributing device connector 455 into the second end of the connector 470, the protrusion or tab can be inserted and received in the second end of the connector 470.

As illustrated in FIG. 4B, upon rotation of the gas distributing device 450 (including the gas distributing device connector 455), the locking portion can engage with the corresponding locking portion inside the second end of the connector 470. In some embodiments, the locking portion or the corresponding locking portion can include inclined portions such that the rotation of the gas distributing device connector 455 provides a further secured connection between the gas distributing device connector 455 and the connector 470. In some embodiments, the locking connection can be provided by a snap-fit connection. The above disclosure is not intending to be limiting, in which other locking connections can be used, for example, cam-type locks, screw couplings, screw links, or the like. In some embodiments, a scaling ring can be provided along an outer surface of the second end of the gas distributing device connector 455 to provide a fluidly scaled connection. Moreover, while the gas distributing device connector 455 has been discussed herein as being connected to the connector 470, it is understood that the gas distributing device connector 455 can be directly connected to the shell of the substrate container 400 using the same or similar structures as discussed above.

As seen in FIG. 4C, after the locking connection between the gas distributing device connector 455 and the connector 470 has been completed, the gas distributing device 450 is installed in the interior space of the substrate container 400. In some embodiments, the gas distributing device 450 can be further secured inside the interior space of the substrate container at an end opposite the gas distributing device connector 455, e.g., via bracket, screws, clips, or the like to provide further support of the gas distributing device 450 along an interior portion of the substrate container 400.

As such, by having the gas distributing gas connector 455 and connector 470 as discussed herein, such combination allows the front gas distributing device 450 to be removed or replaced by simply rotating the amplifier, diffuser, or manifold to lock or unlock the front gas distributing device from the substrate container 400 in which minimal operations can be performed inside the shell of the substrate container. As such, a simple and effective purge gas assembly can be provided to transport purge gas from an inlet and a rear purge module to a front gas distributing device via a flexible polymer tube through the shell of the substrate container without having to modify the substrate container or drill holes into the bottom plate, in which the components can be simply twist-locked or snap-fit connected together to provide reliable connections. Such purge gas flow distribution can be routed within existing FOUP geometries with minimal modifications, e.g., since the pre-assembly of the purge gas assembly can be done externally of the substrate container.

As illustrated in FIGS. 4A, 4B, 4C, in an embodiment, the gas distributing device 450 can be an amplifier assembly, in which a deflector engages with a gas distributor. The gas distributor can be configured to provide a purging gas to purge the interior of the substrate container 400. The gas distributor can distribute the purging gas in a longitudinal direction relative to the gas distributor. The gas distributor can be a nozzle, a diffuser, or the like. In some embodiments, the gas distributor can be an elongated member. The gas distributor can protrude from and into the substrate container 400.

The gas distributor can be a diffuser having a porous body. The porous body can include a channel in the longitudinal direction to distribute the purging gas in the longitudinal direction. After being distributed in the channel, the purging gas can then flow radially through the porous body, in radial directions R, to be released into the interior of the substrate container 400.

The deflector can have a longitudinal opening and a deflection surface. The longitudinal opening and the deflection surface can collectively guide a purging gas to flow in a predetermined direction by controlling a flow direction of at least a portion of the purging gas leaving the gas distributor. The predetermined direction can be based on desired flow through the substrate container 400. The deflector can be positioned and/or oriented such that the flow is directed in the predetermined direction. The deflector can be oriented such that the longitudinal opening is centered on a line connecting the gas distributor and a center of the substrate container 400. The deflector can be a curved structure disposed to direct and/or deflect the purging gas flowing in the interior of the substrate container 400. In some embodiments, the deflector can be a non-permeable and/or non-porous material to the purging gas. For example, the deflector can be made with plastic, metal, or the like.

In some embodiments, the deflector engages with the gas distributor. The deflector is indexed to the gas distributor by an indexer to maintain a relative angular position between the gas distributor and the deflector and/or the deflection surface. The indexer can be one or more features or structures that can maintain a relative angular or rotational position in a repeatable manner, for example, by rotating the gas distributor in discrete angles. In some embodiments, movements of the substrate container or fluid flows in the interior of the substrate container 400 can influence the deflector or the gas distributor relative to the substrate container 400. The influence can result in, but not limited to, a change in relative angular position between, for example, the deflector and/or the gas distributing device 450 and the substrate container 400. The indexer can maintain the relative angular position by resisting a force that may move or rotate the gas distributing device 450, e.g., including the gas distributor or the deflector, relative to the substrate container 400 by providing a connection, e.g., via gas distributing device connector 455. The connection can be between the deflector and the gas distributor, the deflector and the substrate container 400, or the gas distributor and the substrate container 400. In some embodiments, the connection can be among the gas distributor, the deflector, and the substrate container 400. In some embodiments, the connection is rigid to resist or dissipate the force that may move or rotate the gas distributor or the deflector relative to the substrate container 400. In some embodiments, the deflector can directly or indirectly engage with gas distributor via the indexer forming, for example, an interference fit, a snap-fit, a clip mechanism, or the like, creating friction between the deflector and gas distributor to resist the influence.

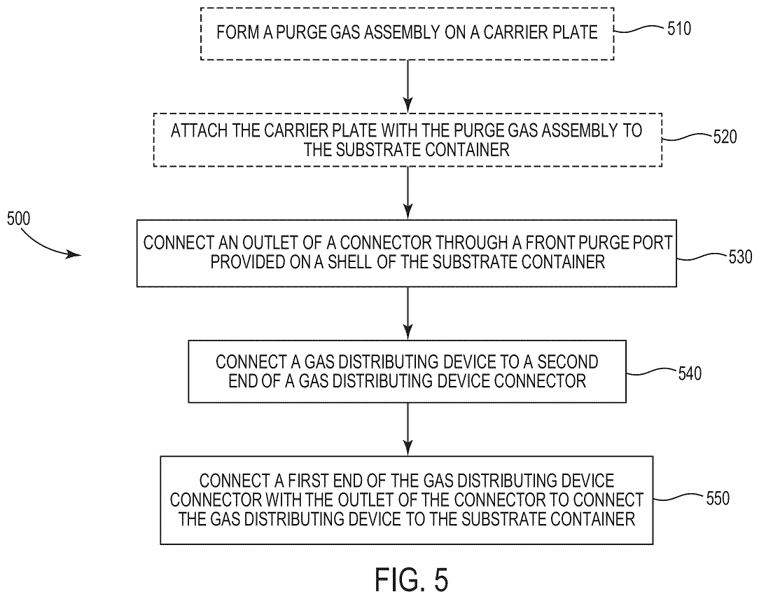

FIG. 5 shows a flowchart of a method of assembling a substrate container having a gas distributing device, according to an embodiment. Method 500 includes optionally forming a purge gas assembly on a bottom plate at 510; optionally attaching the bottom plate with the purge gas assembly to the substrate container at 520; connecting an outlet of a connector of the purge gas assembly to a front purge port provided on a shell of the substrate container at 530; connecting a gas distributing device to a second end of a gas distributing device connector at 540; and connecting a first end of the gas distributing device connector with the outlet of the connector to connect the gas distributing device to the substrate container at 550.

Form a purge gas assembly on a bottom plate at 510. The forming of the purge gas assembly on the bottom plate can be an optional pre-assembly step. In the pre-assembly step, a purge gas assembly that includes tubing, valve(s), and a gas distributor can be attached or molded together with a top surface of a bottom plate. In some embodiments, the pre-assembly can include one or more of: attaching tubing to connect the second opening of the chamber for distributing or controlling purge gas to a front gas distributing device; snap-fitting a snap-fit connection on the tubing and the second opening of the chamber or snap-fitting a snap-fit connection on the tubing and the connector of the purge gas assembly; attaching a control valve to the second opening of the chamber for regulating the flow of purge gas; snap-fitting a snap-fit connection on an inlet of the control valve to the second opening of the chamber; and connecting the purge module and diffuser prior to attaching to the substrate container. In an embodiment, tubing is connected to the combination of gas distributor and purge module (if assembled prior to attaching to the substrate container), e.g., 130 of FIG. 1, at one end thereof, and the connector connected to the other end of the tubing, as discussed above. As such, the purge gas assembly is configured to deliver purge gas from the rear purge inlet at the combination of gas distributor and purge module, e.g., 130 of FIG. 1, to the front gas distributing device through the substrate container, e.g., through the shell of the substrate container to the front gas distributing device(s). That is, since the purge gas assembly includes the control valve, tubing, and the connector to distribute or control the purge gas through the shell to the front gas distributing device(s), e.g., amplifier, diffuser, or manifold, the purge gas can be diverted from the rear inlet ports to the front purge ports and front gas distributing devices, e.g., inside a FOUP. Moreover, since the components of the purge gas assembly, e.g., the control valve, tubing, and the connector, can be configured to have a twist-lock or snap-fit connection and scaling, e.g., using a scaling ring, the components can be easily installed and connected together. Such twist-lock or snap-fit connection also can allow the front gas distributing device, e.g., amplifier, diffuser, or manifold, to be removed and replaced from the substrate container by simply rotating to lock or un-lock it from the connector or shell of the substrate container, as further discussed below.

In some embodiments, the attaching of the purge gas assembly can further include attaching a second purge gas assembly to the bottom plate prior to attaching the bottom plate to the bottom wall of the substrate, in which the second purge gas assembly includes a second combination gas distributor and purge module. While the attachment of the purge gas assembly to a bottom plate is discussed herein, it is understood that such disclosure is not intended to be limiting. For example, in an embodiment, the purge gas assembly can be a stand-alone unit for installation to the substrate container. The method can then proceed to 520.

Attach the bottom plate with the purge gas assembly to the substrate container at 520. After the purge gas assembly is attached to the bottom plate, the bottom plate having the purge gas assembly can optionally be attached to the substrate container. That is, when assembling the substrate container, the bottom plate including the purge gas assembly can be attached to the bottom wall of the substrate container to define the bottom plate of the substrate container and the purge module and rear diffuser can be attached subsequently, to form a complete substrate container system. The attachment of the bottom plate can be securely fixed, e.g., using tabs, screws, or other fastening devices, and not intended to be able to be disassembled to be integrally formed or removably attachable, as necessary. The method can then proceed to 530.

Connect an outlet of a connector through a front purge port provided on a shell of the substrate container at 530. The connector includes a base portion that has an inlet and an outlet, in which the inlet is connected to the tubing, as discussed above. The connector further includes a connector body having a first end and a second end, in which the first end is configured to rotatably connect with the outlet of the base portion, and the second end is configured to connect to the front purge port of the substrate container. In some embodiments, the connector body can be connected to the base portion and the connector connected to the shell of the substrate container. In other embodiments, the connector body can be connected to the shell of the substrate container and rotatably connected to the base portion of the connector. In some embodiments, the connector body and the base portion can include corresponding locking portions that are configured to provide a locking connection between the connector body and the base portion by a rotation of the connector body received on the outlet of the base portion. In other embodiments, the connector body can have a snap-fit connection with the base portion. The snap-fit connection can include flexible components that can deform when a force is applied, e.g., using a twisting or pushing force, such that an interlocking occurs with the corresponding components when in the final position, e.g., restoration of the components.

Furthermore, the connector body having the second end is configured to connect to at least one of the front purge port of the substrate container or a gas distributing device connector connected to the gas distributing device. The connection between the second end of the connector body and the front purge port can be as follows. The second end of the connector can include an abutment portion and cavity for connecting to the front purge port. In an embodiment, the second end of the connector can be inserted into the front purge port such that the abutment portion at the second end abuts the protrusion formed along the inner surface of the side walls. The cavity of the second end of the connector can be configured to accommodate the walls forming the front purge port such that a main body of the connector can be adjacent the shell of the substrate container. A sealing ring can be provided on the outer surface of the second end such that when the second end is inserted into the walls of the front purge port a fluidly sealed connection is provided. The method can then proceed to 540.

Connect a gas distributing device to a second end of a gas distributing device connector at 540. The assembling can further include attaching the gas distributing device to the gas distributing device connector. The gas distributing device can be a diffuser, manifold, membrane, portions having slits or nozzles or is made of porous material, elbows, or flow diverters, or similar structures that is able to direct the purge gas into the interior of the substrate container, and combinations of the same. The gas distributing device connector includes a first end and a second end. The first end and the second end can be disposed at an angle with respect to each other. In some embodiments, the angle can be at or about 90-degree angle. The first end can include threaded portions for connecting to the gas distributing device. The threaded portions can be configured to provide a screw connection, ribbed connection, or press-fit connection between the gas distributing device connector and the gas distributing device. The method can then proceed to 550.

Connect a first end of the gas distributing device connector with the outlet of the connector to connect the gas distributing device to the substrate container at 550. The second end of the gas distributing device connector includes an abutment portion and a locking portion. The abutment portion is configured to engage an interior portion or surface of the shell of the substrate container, e.g., along the inner surface of the side wall. In some embodiments, the abutment portion can abut against the protrusions. As such, when the gas distributing device connector is connected with the connector, the abutment portion can be configured to prevent or limit the extension of the second end of the gas distributing device connector out of the shell of the substrate container or provide an opposing surface for providing a secured connection with the connector, e.g., counter forces to securing the gas distributing device to the substrate container or purge gas assembly. In some embodiments, the locking portion of the second end of the gas distributing device connector can be a protrusion or tab that is configured to engage with a corresponding locking portion provided along an inner surface of the second end of the connector. As such, when initially connecting the second end of the gas distributing device connector into the second end of the connector, the protrusion or tab can be inserted and received in the second end of the connector.

Step 550 can further include rotating the gas distributing device and the gas distributing device connector in the connector to provide a locking connection. After the second end of the gas distributing device connector is inserted into the second end of the connector, the locking connection can be provided by a rotation of the gas distributing device connector inside the connector such that the locking portion of the second end engages with the corresponding locking portion inside the second end of the connector.

The method can further include securing or attaching the gas distributing device inside the substrate container. The securement can include, but not limited to, using bracket, screws, clips, or the like to provide further support of the gas distributing device inside the substrate container.

As such, by having a method using the gas distributing gas connector and connector as discussed herein, such combination allows the front gas distributing device to be removed or replaced by simply rotating the amplifier, diffuser, or manifold to lock or unlock the front gas distributing device from the substrate container by minimally requiring any operations be performed inside the shell of the substrate container. As such, a simple and effective purge gas assembly can be provided to transport purge gas from an inlet and a rear purge module to a front gas distributing device via a flexible polymer tube through the shell of the substrate container without having to modify the substrate container or drill holes into the bottom plate, in which the components can be simply twist-locked or snap-fit connected together to provide reliable connections. Such purge gas flow distribution can be routed within existing FOUP geometries with minimal modifications, e.g., since the pre-assembly of the purge gas assembly can be done externally of the substrate container.

As such, the substrate container having the purge gas assembly or the purge gas assembly connector, as discussed herein, have at least the following benefits:

A structure that is configured to deliver purge gas to front gas distributing devices, such as, amplifiers, manifolds, or diffusers, from existing rear purge gas inlet locations, in which the purge gas is delivered through or along the substrate container shell into the front gas distributing devices.

A structure that is configured to control or distribute purge gas from the rear purge gas inlet locations to the front of the substrate container by dividing or diverting portions of the purge gas such that the amount of purge gas can be adjusted for optimal performance.

A method to transport or control the flow of the purge gas from the inlet location(s) to the gas distributing devices inside the substrate container, and, especially, from a rear purge module to the front gas distributing devices and an assembly structure for allowing the same.

A method and structure that allows installation and insertion of the gas distributing devices into the substrate container without requiring (or minimally requiring) any operations to be performed inside the substrate container, e.g., especially in portions of the interior space of the substrate container in which the substrates can be installed. As such, such installation can reduce the likelihood of installation errors or reduce particle generation or addition of contaminants within the container body or shell of the substrate container. This can in turn reduce the loss of substrates, such as wafers, and improve yields from processes using substrate containers that include the purge gas assembly(s) or gas distributing device(s).

### Aspects:

It is understood that any of aspects 1-11 can be combined with any of aspects 12-16 and/or 17-19, and any of aspects 12-16 can be combined with any of aspects 1-11 and 17-19, and any of aspects 17-29 can be combined with any of aspects 1-16.
Aspect 1. A connector for a purge gas assembly for a substrate container, the connector comprising: a base portion having an inlet and an outlet, wherein the inlet is configured to connect with a tubing connected to the purge gas assembly; a connector body having a first end and a second end, wherein the first end is configured to rotatably connect with the outlet of the base portion, and the second end is configured to connect to an opening provided on a substrate container.
Aspect 2. The connector according to Aspect 1, wherein the connector body and the base portion have corresponding locking portions that are configured to provide a locking connection between the connector body and the base portion by a rotation of the connector body received on the outlet of the base portion.
Aspect 3. The connector according to Aspect 2, wherein the locking portions have corresponding incline portions for securing the locking connection between the connector body and the base portion.
Aspect 4. The connector according to any of Aspects 1-3, wherein the second end of the connector body and the opening of the substrate container each include one or more corresponding engagement features configured to connect the connector body to the substrate container.
Aspect 5. The connector according to any of Aspects 1-4, wherein the first end and second end of the connector body are disposed at an angle with respect to each other.
Aspect 6. The connector according to any of Aspects 1-5, further comprising a gas distributing device connector, wherein a first end of the gas distributing device connector is configured to connect with the second end of the connector body and a second end of the gas distributing device connector is configured to connect with a gas distributing device.
Aspect 7. The connector according to Aspect 6, wherein the first end of the gas distributing device connector and the second end of the connector body comprise corresponding second locking portions that are configured to provide a locking connection between the connector body and the gas distributing device connector.
Aspect 8. The connector according to Aspect 7, wherein the second locking portions are configured to provide the locking connection by a rotation of the first end of the gas distributing device connector received in the connector body.
Aspect 9. The connector according to any of Aspects 6-8, wherein the second end of the gas distributing device connector comprises one or more engagement features configured to engage the gas distributing device.
Aspect 10. The connector according to any of Aspects 6-9, wherein the gas distributing device connector comprises an abutment portion for abutting against an interior surface of the substrate container.
Aspect 11. The connector according to any of Aspects 6-10, wherein the gas distributing device comprises at least one of an amplifier, a diffuser, or manifold assembly for connecting to an interior portion of the substrate container.
Aspect 12. A substrate container comprising: a shell; a connector connected to an opening provided on a side wall of the shell, wherein the connector comprises a base portion having an inlet and an outlet and a connector body having a first end and a second end, wherein the first end of the connector body is rotatably connected with the outlet of the base portion, and second end of the connector body is connected to the opening of the shell; a gas distributing device connector comprising a first end and a second end, wherein the first end of the gas distributing device connector is connected with the second end of the connector body and a second end of the gas distributing device connector is configured to connect with a gas distributing device.
Aspect 13. The substrate container according to Aspect 12, further comprising the gas distributing device provided in an interior space of the substrate container.
Aspect 14. The substrate container according to Aspect 13, wherein the gas distributing device comprises at least one of an amplifier, a diffuser, or a manifold assembly connected to an interior portion of the substrate container.
Aspect 15. The substrate container according to any of Aspects 12-14, wherein the connector body and the base portion have corresponding locking portions to have a locking connection between the connector body and the base portion.
Aspect 16. The substrate container according to any of Aspects 12-15, wherein the first end of the gas distributing device connector and the second end of the connector body comprise corresponding second locking portions to have a second locking connection between the connector body and the gas distributing device connector.
Aspect 17. A method for assembling a substrate container having a gas distributing device comprising: connecting an outlet of a connector through a front purge port provided on a shell of the substrate container; connecting a gas distributing device to a second end of a gas distributing device connector; and connecting a first end of the gas distributing device connector with the outlet of the connector to connect the gas distributing device to the substrate container.
Aspect 18. The method of Aspect 17, wherein the connecting of the first end of the gas distributing device with the outlet of the connector includes rotating the gas distributing device and the gas distributing device connector in the connector to provide a locking connection.
Aspect 19. The method of any of Aspects 17-18, further comprising forming a purge gas assembly by attaching tubing and the connector on a bottom plate, wherein the method further comprises attaching the bottom plate with the purge gas assembly to the substrate container prior to connecting the first end of the gas distributing device connector with the outlet of the connector.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A connector for a purge gas assembly for a substrate container, the connector comprising:
a base portion having an inlet and an outlet, wherein the inlet is configured to connect with a tubing connected to the purge gas assembly; and
a connector body having a first end and a second end, wherein the first end is configured to rotatably connect with the outlet of the base portion, and the second end is configured to connect to an opening provided on a substrate container.

2. The connector according to claim 1, wherein the connector body and the base portion have corresponding locking portions that are configured to provide a locking connection between the connector body and the base portion by a rotation of the connector body received on the outlet of the base portion.

3. The connector according to claim 2, wherein the locking portions have corresponding incline portions for securing the locking connection between the connector body and the base portion.

4. The connector according to claim 1, wherein the second end of the connector body and the opening of the substrate container each include one or more corresponding engagement features configured to connect the connector body to the substrate container.

5. The connector according to claim 1, wherein the first end and second end of the connector body are disposed at an angle with respect to each other.

6. The connector according to claim 1, further comprising a gas distributing device connector, wherein a first end of the gas distributing device connector is configured to connect with the second end of the connector body and a second end of the gas distributing device connector is configured to connect with a gas distributing device.

7. The connector according to claim 6, wherein the first end of the gas distributing device connector and the second end of the connector body comprise corresponding second locking portions that are configured to provide a locking connection between the connector body and the gas distributing device connector.

8. The connector according to claim 7, wherein the second locking portions are configured to provide the locking connection by a rotation of the first end of the gas distributing device connector received in the connector body.

9. The connector according to claim 6, wherein the second end of the gas distributing device connector comprises one or more engagement features configured to engage the gas distributing device.

10. The connector according to claim 6, wherein the gas distributing device connector comprises an abutment portion for abutting against an interior surface of the substrate container.

11. The connector according to claim 6, wherein the gas distributing device comprises at least one of an amplifier, a diffuser, or manifold assembly for connecting to an interior portion of the substrate container.

12. A substrate container comprising:
a shell;
a connector connected to an opening provided on a side wall of the shell, wherein the connector comprises a base portion having an inlet and an outlet and a connector body having a first end and a second end, wherein the first end of the connector body is rotatably connected with the outlet of the base portion, and second end of the connector body is connected to the opening of the shell; and
a gas distributing device connector comprising a first end and a second end, wherein the first end of the gas distributing device connector is connected with the second end of the connector body and a second end of the gas distributing device connector is configured to connect with a gas distributing device.

13. The substrate container according to claim 12, further comprising the gas distributing device provided in an interior space of the substrate container.

14. The substrate container according to claim 13, wherein the gas distributing device comprises at least one of an amplifier, a diffuser, or a manifold assembly connected to an interior portion of the substrate container.

15. The substrate container according to claim 12, wherein the connector body and the base portion have corresponding locking portions to have a locking connection between the connector body and the base portion.

16. The substrate container according to claim 12, wherein the first end of the gas distributing device connector and the second end of the connector body comprise corresponding second locking portions to have a second locking connection between the connector body and the gas distributing device connector.

17. A method for assembling a substrate container having a gas distributing device comprising:
connecting an outlet of a connector through a front purge port provided on a shell of the substrate container;
connecting a gas distributing device to a second end of a gas distributing device connector; and
connecting a first end of the gas distributing device connector with the outlet of the connector to connect the gas distributing device to the substrate container.

18. The method of claim 17, wherein the connecting of the first end of the gas distributing device with the outlet of the connector includes rotating the gas distributing device and the gas distributing device connector in the connector to provide a locking connection.

19. The method of claim 17, further comprising forming a purge gas assembly by attaching tubing and the connector on a bottom plate, wherein the method further comprises attaching the bottom plate with the purge gas assembly to the substrate container prior to connecting the first end of the gas distributing device connector with the outlet of the connector.
